(19) United States
(12) Patent Application Publication
(10) Pub. No.: US 2010/0097865 A1
(43) Pub. Date: Apr. 22, 2010

(54) DATA TRANSMISSION CIRCUIT AND A SEMICONDUCTOR INTEGRATED CIRCUIT USING THE SAME

(75) Inventors: Shin-Deok Kang, Ichon (KR); Dong-Uk Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 12/347,301

(22) Filed: Dec. 31, 2008

(30) Foreign Application Priority Data
Oct. 21, 2008 (KR) 10-2008-0103288

(51) Int. Cl. G11C 7/00; G11C 8/00

(52) U.S. Cl. 365/189.05; 365/193; 365/194; 365/230.03

(57) ABSTRACT

A data transmission circuit includes a data input unit configured to latch data in response to a data strobe signal and to output the data as input data, and a data input timing control unit configured to latch the input data in response to the data strobe signal delayed for a predetermined time interval and to output the input data to a bank group as delay data.

### CROSS-REFERENCES TO RELATED APPLICATION

The present application claims priority under 35 U.S.C. 119(a) to Korean application number 10-2008-0103288, filed on Oct. 21, 2008, in the Korean Intellectual Property Office, which is incorporated herein by reference in its entirety as if set forth in full.

### BACKGROUND

1. Technical Field

The embodiments described herein relate to a semiconductor integrated circuit, and more particularly, to a data transmission circuit and a semiconductor integrated circuit using the same.

2. Related Art

In general, a semiconductor integrated circuit stores data or outputs the stored data. For example, a data input circuit receives the data so that the data is stored in the semiconductor integrated circuit. For purposes of convention, data input from an exterior of the semiconductor integrated circuit will be referred to as external data. The external data is input to the semiconductor integrated circuit in the form of serial data, and the serial data is converted to parallel data in the semiconductor integrated circuit. For further purposes of convention, the parallel data will be referred to as data.

FIG. 1 is a schematic block diagram of a conventional data input circuit of a semiconductor integrated circuit. In FIG. 1, the semiconductor integrated circuit 1 includes a data input unit 10, first to fourth delay units 21 to 24, an up-bank group 30 and a down-bank group 40.

The data input unit 10 latches first to fourth data signals ‘data<0:3>’ in response to a data strobe signal ‘dinstb’.

The first to fourth delay units 21 to 24 delay the latched data signals ‘data<0:3>_in’ to output first to fourth delay data signal ‘data<0:3>_dl’, respectively.

The up-bank group 30 includes first to fourth banks ‘bank0’ to ‘bank3 ’, and the down-bank group 40 includes fifth to eighth banks ‘bank4 ’ to ‘bank7 ’. The up-bank and down-bank groups 30 and 40 receive the first to fourth delay data signals ‘data<0:3>_dl’, respectively. Here, only an activated one of the first to eighth banks ‘bank0’ to ‘bank7 ’ stores the first to fourth delay data signals ‘data<0:3>_dl’.

A conventional operation in which the semiconductor integrated circuit 1 stores data will be referred to as a write operation, and time required when the data input from the exterior is stored in the semiconductor integrated circuit 1 will be referred to as a write operation margin.

In FIG. 1, the conventional semiconductor integrated circuit 1 includes a plurality of delay units 21 to 24 for the write operation margin.

Although current consumption in the semiconductor integrated circuit 1 increases due to current consumed by the delay units 21 to 24, the delay units are used due to the write operation margin. Furthermore, data must be stored only in activated banks of the up-bank or down-bank group. However, the data is substantially input to the up-bank and down-bank groups, thereby increasing current consumption of the semiconductor integrated circuit 1.

### SUMMARY

A data transmission circuit capable of reducing the amount of current consumed when a semiconductor integrated circuit stores data, and the semiconductor integrated circuit using the same are described herein.

In one aspect, a data transmission circuit includes a data input unit configured to latch data in response to a data strobe signal and to output the data as input data, and a data input timing control unit configured to latch the input data in response to the data strobe signal delayed for a predetermined time interval and to output the input data to a bank group as delay data.

In another aspect, a semiconductor integrated circuit includes a plurality of banks, each configured to receive delay data through a global line, a data input unit configured to latch data in response to a data strobe signal and to output the data as input data, and a data input timing control unit configured to output the input data to the global line as delay data in response to the data strobe signal.

In still another embodiment, a method for data transmission in a semiconductor apparatus, the method comprising latching data in response to a data strobe signal, outputting the data as input data,

delaying the data strobe signal for a predetermined time interval, latching the input data in response to the delayed data strobe signal, and outputting the input data as delay data.

Theses and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a schematic block diagram of a conventional data input circuit of a semiconductor integrated circuit;

FIG. 2 is a schematic block diagram of an exemplary data input circuit of a semiconductor integrated circuit according to one embodiment;

FIG. 3 is a schematic block diagram of an exemplary switching unit capable of being implemented in the circuit of FIG. 2 according to one embodiment;

FIG. 4 is a schematic block diagram of another exemplary data input circuit of a semiconductor integrated circuit according to another embodiment;

FIG. 5 is a schematic block diagram of an exemplary controller capable of being implemented in the circuit of FIG. 4 according to one embodiment;

FIG. 6 is a schematic block diagram of an exemplary encoding unit capable of being implemented in the controller of FIG. 5 according to one embodiment; and

FIG. 7 is a schematic block diagram illustrating of an exemplary selection delay unit capable of being implemented in the controller of FIG. 5 according to one embodiment.

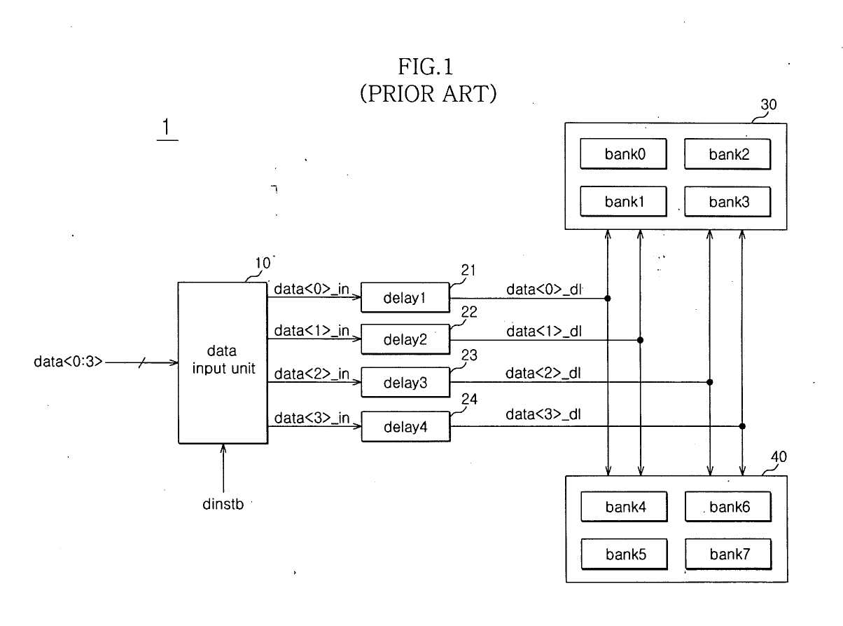

### DETAILED DESCRIPTION

For purposes of explanation, data input from an exterior of a semiconductor integrated circuit will be referred to as external data and can be input to the semiconductor integrated circuit in the form of serial data. Here, the serial data can be converted to parallel data in the semiconductor integrated circuit. In addition, the parallel data will be referred to as data.

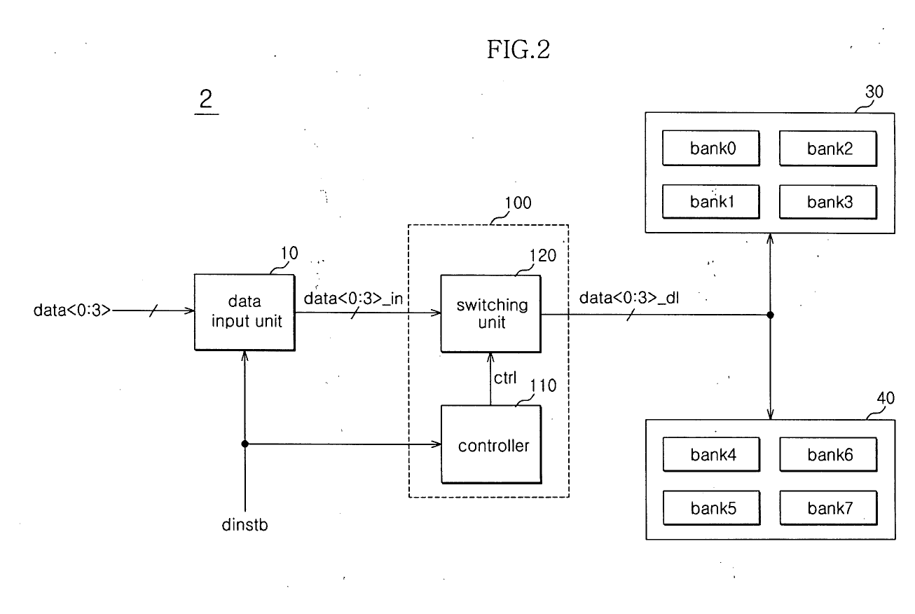

FIG. 2 is a schematic block diagram of an exemplary data input circuit 2 of a semiconductor integrated circuit according to one embodiment. In FIG. 2, the semiconductor integrated circuit 2 can be configured to include a data input unit 10, a data transmission circuit having a data input timing control unit 100, an up-bank group 30 and a down-bank group 40. Here, for example, first to fourth delay data signals ‘data<0:3>_dl’ output from the data input timing control unit 100 can be substantially simultaneously input to the up-bank group 30 and the down-bank group 40.

If a data strobe signal ‘dinstb’ is enabled, then the data input unit 10 can receive first to fourth data signals ‘data<0:3>’ to output first to fourth input data signals ‘data<0:3>_in’. For example, the data input unit 10 can be configured to latch the first to fourth data signals ‘data<0:3>’ in response to the data strobe signal ‘dinstb’. Here, signals output from the data input unit 10 will be referred to as the first to fourth input data signals ‘data<0:3>_in’.

In FIG. 2, the data input timing control unit 100 can be configured to output the first to fourth input data signals ‘data<0:3>_in’ as first to fourth delay data signals ‘data<0:3>_dl’ in response to the data strobe signal ‘dinstb’. For example, if the data strobe signal ‘dinstb’ is enabled and a predetermined time interval lapses, then the data input timing control unit 100 can output the first to fourth delay data signals ‘data<0:3>_dl’.

In FIG. 2, the data input timing control unit 100 can be configured to include a controller 110 and a switching unit 120.

The controller 110 can output a control signal ‘ctrl’ by delaying the data strobe signal ‘dinstb’. For example, the controller 110 can be configured as general delay circuit that delays the data strobe signal ‘dinstb’.

The switching unit 120 can be configured to output the first to fourth input data signal ‘data<0:3>_in’ as the first to fourth delay data signals ‘data<0:3>_dl’ in response to the control signal ‘ctrl’. For example, if the control signal ‘ctrl’ is enabled, then the switching unit 120 can output the first to fourth input data signals ‘data<0:3>_in’ as the first to fourth delay data signals ‘data<0:3>_dl’.

The up-bank group 30 can include first to fourth banks ‘bank0’ to ‘bank3’, and the down-bank group 40 can include fifth to eighth banks ‘bank4’ to ‘bank7’. Accordingly, the first to fourth delay data signals ‘data<0:3>_dl’ can be input to the first to eighth banks ‘bank0’ to ‘bank7’ through global lines. In addition, only an activated one of the first to eighth banks ‘bank0’ to ‘bank7’ provided in the up-bank group 30 and the down-bank group 40 can be configured to store the first to fourth delay data signals ‘data<0:3>_dl’.

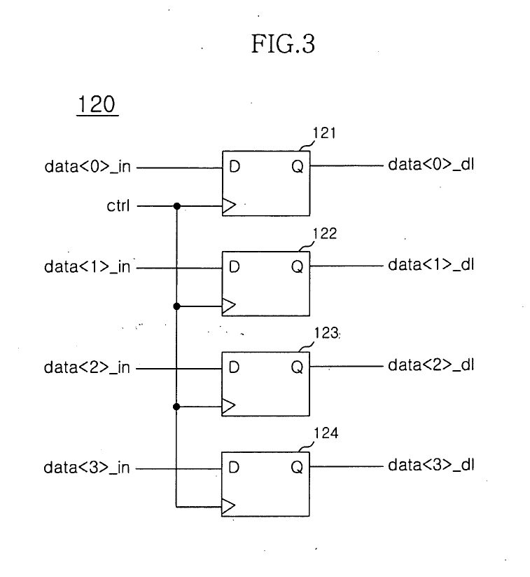

FIG. 3 is a schematic block diagram of an exemplary switching unit 120 capable of being implemented in the circuit of FIG. 2 according to one embodiment. In FIG. 3, the switching unit 120 can include first to fourth flip-flops 121 to 124. The first flip-flop 121 can be configured to receive the first input data signal ‘data<0>_in’ through an input terminal D thereof to output the first delay data signal ‘data<0>_dl’ through an output terminal Q thereof. Furthermore, the first flip-flop 121 can be configured to receive the control signal ‘ctrl’ through a clock input terminal thereof.

The second flip-flop 122 can be configured to receive the second input data signal ‘data<1>_in’ through an input terminal D thereof to output the second delay data signal ‘data<1>_dl’ through an output terminal Q thereof. Furthermore, the second flip-flop 122 can be configured to receive the control signal ‘ctrl’ through a clock input terminal thereof.

The third flip-flop 123 can be configured to receive the third input data signal ‘data<2>_in’ through an input terminal D thereof to output the third delay data signal ‘data<2>_dl’ through an output terminal Q thereof. Furthermore, the third flip-flop 123 can be configured to receive the control signal ‘ctrl’ through a clock input terminal thereof.

The fourth flip-flop 124 can be configured to receive the fourth input data signal ‘data<3>_in’ through an input terminal D thereof to output the fourth delay data signal ‘data<3>_dl’ through an output terminal Q thereof. Furthermore, the fourth flip-flop 124 can be configured to receive the control signal ‘ctrl’ through a clock input terminal thereof.

Accordingly, if the control signal ‘ctrl’ is enabled, then the first to fourth flip-flops 121 to 124 can receive the corresponding input data signals ‘data<0:3>_in’ through the input terminals D thereof to output the corresponding delay data signals ‘data<0:3>_dl’ through the output terminals Q thereof, respectively.

An exemplary operation of the semiconductor integrated circuit 2 using the data transmission circuit will be described with reference to FIGS. 2 and 3.

In FIG. 2, the data strobe signal ‘dinstb’ is generated in the semiconductor integrated circuit 2 when an operation, such as a write operation, for example, of storing data in the bank is performed. Furthermore, the first to fourth data signals are exemplary for purposes of explanation. Accordingly, other numbers and types of data signals can be implemented.

If the data strobe signal ‘dinstb’ is enabled, then the data input unit 10 can receive the first to fourth data signals ‘data<0:3>’ to output the first to fourth input data signals ‘data<0:3>_in’. Then, the controller 110 can output the control signal ‘ctrl’ by delaying the data strobe signal ‘dinstb’.

If the control signal ‘ctrl’ is enabled, then the switching unit 120 can receive the first to fourth input data signals ‘data<0:3>_in’ to output the first to fourth delay data signals ‘data<0:3>_dl’. For example, as shown in FIG. 3, the switching unit 120 can include the first to fourth flip-flops 121 to 124 to latch the first to fourth input data signals ‘data<0:3>_in’ even if the enabled control signal ‘ctrl’ is disabled.

Next, the first to fourth delay data signals ‘data<0:3>_dl’ can be input to the up-bank and down-bank groups 30 and 40. For example, the first to fourth delay data signals ‘data<0:3>_dl’ can be stored only in an activated one of the first to eighth banks ‘bank0’ to ‘bank7’ provided in the up-bank and down-bank groups 30 and 40.

Accordingly, input timing of all data input to the banks can be controlled using the switching unit and the control signal obtained by delaying the data strobe signal. Thus, the amount of current consumed when data is transferred to the bank can be reduced because only one delay unit is used.

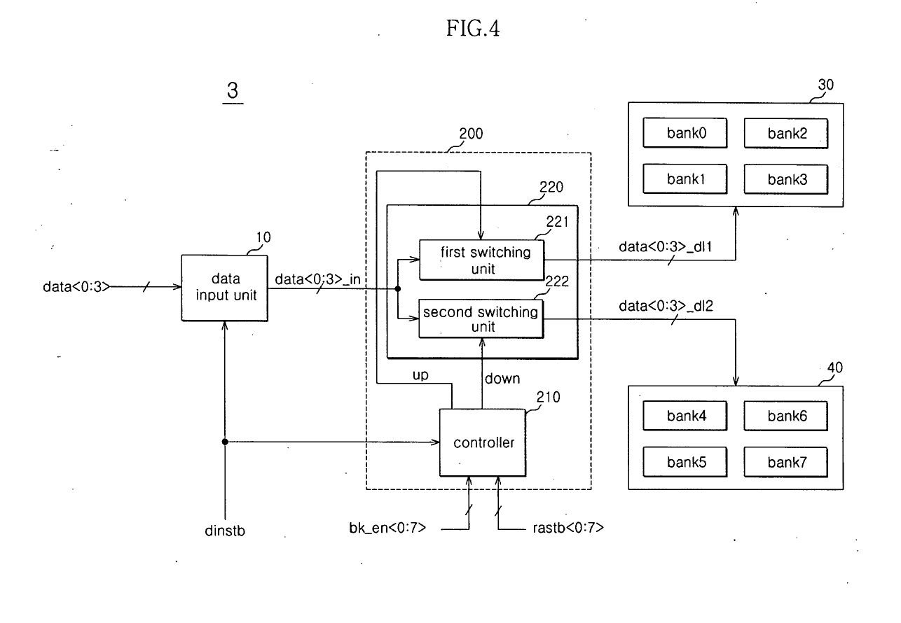

FIG. 4 is a schematic block diagram of another exemplary data input circuit 3 of a semiconductor integrated circuit according to another embodiment. In FIG. 4, the semiconductor integrated circuit can be configured to include a data transmission circuit 3 having a data input unit 10, and a data input timing control unit 200, an up-bank group 30 and a down-bank group 40. The data input timing control unit 200 can be configured to selectively output a first delay data signal group ‘data<0:3>_dl1’ to the up-bank group 30 or output a second delay data signal group ‘data<0:3>_dl2’ to the down-bank group 40 in response to a data strobe signal ‘dinstb’ and bank information signals ‘bk_en<0:7>’ and ‘rastb<0:7>’.

If the data strobe signal ‘dinstb’ is enabled, then the data input unit 10 can receive first to fourth data signals ‘data<0:3>’ to output first to fourth input data signals ‘data<0:3>_in’. For example, the data input timing control unit 200 can be configured to selectively output the first to fourth input data signals ‘data<0:3>_in’ to the up-bank group 30 as the first delay data signal group ‘data<0:3>_dl1’ or to the down-bank group 40 as the second delay data signal group ‘data<0:3>_dl2’ in response to the data strobe signal ‘dinstb’ and the bank information signals ‘bk_en<0:7>’ and ‘rastb<0:7>’. Here, the data input timing control unit 200 can be configured to select the first to fourth input data signals ‘data<0:3>_in’ as the first delay data signal group ‘data<0:3>_d11’ or the second delay data signal group ‘data<0:3>_dl2’ in response to the bank information signals ‘bk_en<0:7>’ and ‘rastb<0:7>’, and then output the selected data group if the data strobe signal ‘dinstb’ is enabled and a predetermined time interval lapses.

The data input timing control unit 200 can include a controller 210 and a selection switching unit 220. The controller 210 can be configured to generate an up-signal ‘up’ or a down-signal ‘down’ in response to the bank information signals ‘bk_en<0:7>’ and ‘rastb<0:7>’ and the data strobe signal ‘dinstb’.

The selection switching unit 220 can be configured to output the first to fourth input data signals ‘data<0:3>_in’ to the up-bank group 30 as the first delay data signal group ‘data<0:3>_dl1’ or to the down-bank group 40 as the second delay data signal group ‘data<0:3>_dl2’ according to whether the up-signal ‘up’ or the down-signal ‘down’ is enabled.

In FIG. 4, the up-bank group 30 can include first to fourth banks ‘bank0’ to ‘bank3’, and the down-bank group 40 can include fifth to eighth banks ‘bank4’ to ‘bank7’.

The first and second delay data signal groups ‘data<0:3>_dl1’ and ‘data<0:3>_dl2’ can be input to the up-bank and down-bank groups 30 and 40 through global lines. For example, the first delay data signal group ‘data<0:3>_dl1’ can be input to the up-bank group 30 through a first global line and the second delay data signal group ‘data<0:3>_dl2’ can be input to the down-bank group 40 through a second global line. In addition, the first delay data signal group ‘data<0:3>_dl1’ or the second delay data signal group ‘data<0:3>_dl2’ can be stored in an activated one of the first to eighth banks ‘bank0’ to ‘bank7’ provided in the up-bank group 30 and the down-bank group 40.

FIG. 5 is a schematic block diagram of an exemplary controller 210 capable of being implemented in the circuit of FIG. 4 according to one embodiment. In FIG. 5, the controller 210 can include an encoding unit 211 and a selection delay unit 212.

The encoding unit 211 can be configured to selectively enable a first selection signal ‘select1’ or a second selection signal ‘select2’ by encoding the bank information signals ‘bk_en<0:7>’ and ‘rastb<0:7>’. Here, for example, the bank information signals ‘bk_en<0:7>’ and ‘rastb<0:7>’ can include first to eighth bank enable signals ‘bk_en<0:7>’ and first to eighth low address strobe signals ‘rastb<0:7>’, respectively. The first to eighth bank enable signals ‘bk_en<0:7>’ can be generated by write and read commands to enable corresponding banks of the first to eighth banks ‘bank0’ to ‘bank7’. The first to eighth low address strobe signals ‘rastb<0:7>’ can be enabled when the corresponding banks of the first to eighth banks ‘bank0’ to ‘bank7’ are activated.

The selection delay unit 212 can be configured to selectively delay the enabled first or second selection signal ‘select1’ or ‘select2’ in response to the data strobe signal ‘dinstb’, thereby generating the enabled up-signal or down-signal ‘up’ or ‘down’.

The encoding unit 211 can be configured to encode the first to eighth bank enable signals ‘bk_en<0:7>’ and the first to eighth low address strobe signals ‘rastb<0:7>’. If the encoding result represents that one of the first to fourth banks ‘bank0’ to ‘bank3’ is activated, then the encoding unit 211 can enable the first selection signal ‘select1’. Furthermore, if the encoding result represents that one of the fifth to eighth banks ‘bank4’ to ‘bank7’ is activated, then the encoding unit 211 can enable the second selection signal ‘select2’.

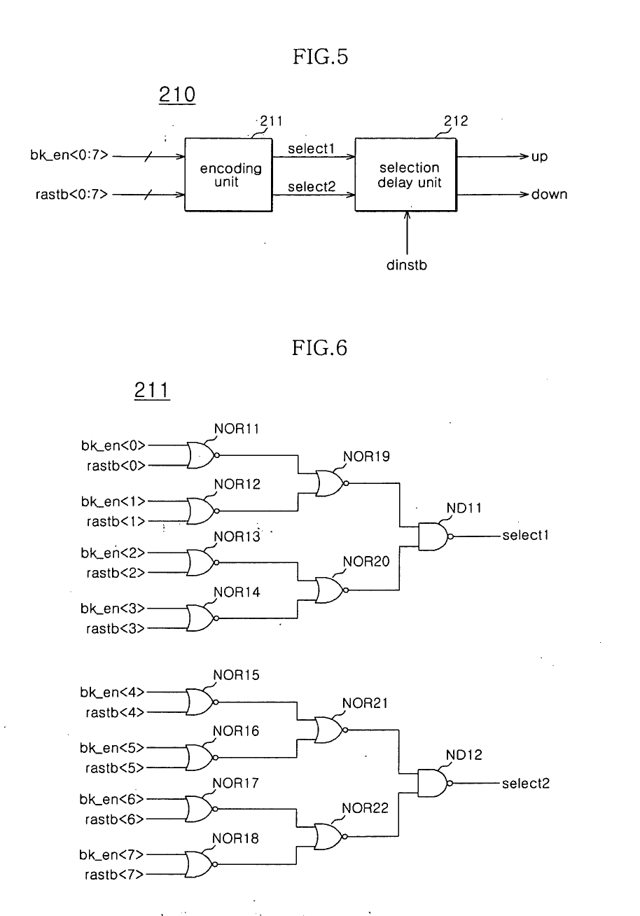

FIG. 6 is a schematic block diagram of an exemplary encoding unit 211 capable of being implemented in the controller of FIG. 5 according to one embodiment. In FIG. 6, the encoding unit 211 can include first to twelfth NOR gates ‘NOR11’ to ‘NOR22’, and first and second NAND gates ‘ND11’ and ‘ND12’.

The first NOR gate ‘NOR11’ can be configured to receive the first bank enable signal ‘bk_en<0>’ and the first low address strobe signal ‘rastb<0>’. The second NOR gate ‘NOR12’ can be configured to receive the second bank enable signal ‘bk_en<1>’ and the second low address strobe signal ‘rastb<1>’. The third NOR gate ‘NOR13’ can be configured to receive the third bank enable signal ‘bk_en<2>’ and the third low address strobe signal ‘rastb<2>’. The fourth NOR gate ‘NOR14’ can be configured to receive the fourth bank enable signal ‘bk_en<3>’ and the fourth low address strobe signal ‘rastb<3>’. The fifth NOR gate ‘NOR15’ can be configured to receive the fifth bank enable signal ‘bk_en<4>’ and the fifth low address strobe signal ‘rastb<4>’. The sixth NOR gate ‘NOR16’ can be configured to receive the sixth bank enable signal ‘bk_en<5>’ and the sixth low address strobe signal ‘rastb<5>’. The seventh NOR gate ‘NOR17’ can be configured to receive the seventh bank enable signal ‘bk_en<6>’ and the seventh low address strobe signal ‘rastb<6>’. The eighth NOR gate ‘NOR18’ can be configured to receive the eighth bank enable signal ‘bk_en<7>’ and the eighth low address strobe signal ‘rastb<7>’. The ninth NOR gate ‘NOR19’ can be configured to receive output signals of the first and second NOR gates ‘NOR11’ and ‘NOR12’. The tenth NOR gate ‘NOR20’ can be configured to receive output signals of the third and fourth NOR gates ‘NOR13’ and ‘NOR14’. The eleventh NOR gate ‘NOR21’ can be configured to receive output signals of the fifth and sixth NOR gates ‘NOR15’ and ‘NOR16’. The twelfth NOR gate ‘NOR22’ can be configured to receive output signals of the seventh and eighth NOR gates ‘NOR17’ and ‘NOR18’.

The first NAND gate ‘ND11’ can be configured to receive output signals of the ninth and tenth NOR gate ‘NOR19’ and ‘NOR20’ to output the first selection signal ‘select1’. The second NAND gate ‘ND12’ can be configured to receive output signals of the eleventh and twelfth NOR gate ‘NOR21’ and ‘NOR22’ to output the second selection signal ‘select2’. Accordingly, the encoding unit 211 can be configured to receive the first to eighth bank enable signals ‘bk_en<0:7>’ and the first to eighth low address strobe signals ‘rastb<0:7>’, which can be enabled at a low level, to generate the first or second selection signal ‘select1’ or ‘select2’, which can be enabled at a high level.

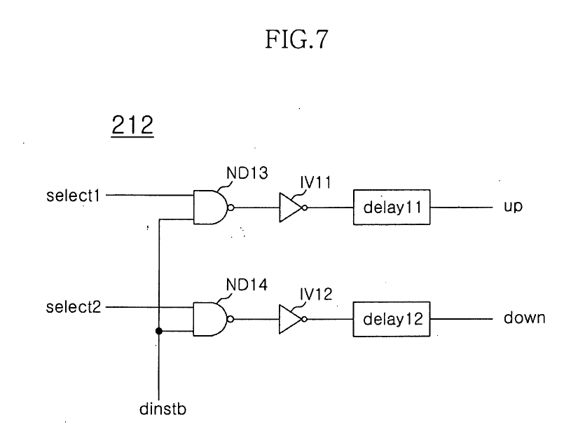

FIG. 7 is a schematic block diagram illustrating of an exemplary selection delay unit 212 capable of being implemented in the controller of FIG. 5 according to one embodiment. In FIG. 7, the selection delay unit 212 can include third and fourth NAND gates ‘ND13’ and ‘ ND14’, first and second inverters ‘IV11’ and ‘IV12’, and first and second delay units ‘delay11’ and ‘delayl2’.

The third NAND gate ‘ND13’ can be configured to receive the first selection signal ‘select1’ and the data strobe signal ‘dinstb’. The fourth NAND gate ‘ND14’ can be configured to receive the second selection signal ‘select2’ and the data strobe signal ‘dinstb’. The first inverter ‘IV11’ can be configured to receive an output signal of the third NAND gate ‘ND13’. The first delay unit ‘delay11’ can be configured to receive an output signal of the first inverter ‘IV11’ to output the up-signal ‘up’. The second inverter ‘IV12’ can be configured to receive an output signal of the fourth NAND gate ‘ND14’. The second delay unit ‘delay12’ can be configured to receive an output signal of the second inverter ‘IV12’ to output the down-signal ‘down’.

If the first selection signal ‘select1’ is enabled at a high level and the data strobe signal ‘dinstb’ is enabled at a high level, then the selection delay unit 212 can enable the up-signal ‘up’ at a high level after delay time of the first delay unit ‘delay11’. Furthermore, if the second selection signal ‘select2’ is enabled at a high level and the data strobe signal ‘dinstb’ is enabled at a high level, then the selection delay unit 212 can enable the down-signal ‘down’ at a high level after delay time of the second delay unit ‘delay12’. Here, for example, the first and second delay units ‘delay11’ and ‘delay12’ may have substantially the same delay time.

In FIG. 7, the selection switching unit 220 can include first and second switching units 221 and 222. Here, for example, the first and second switching units 221 and 222 may have substantially the same configurations as that of the switching unit 120 (in FIG. 3).

However, the first switching unit 221 can receive the up-signal ‘up’ instead of the control signal ‘ctrl’ of the switching unit 120 (in FIG. 3), and the second switching unit 222 can receive the down-signal ‘down’ instead of the control signal ‘ctrl’ of the switching unit 120 (in FIG. 3). For example, if the up-signal ‘up’ is enabled, then the first switching unit 221 can output the first to fourth input data signals ‘data<0:3>_in’ as the first delay data signal group ‘data<0:3>_dl1’. Furthermore, if the down-signal ‘down’ is enabled, then the second switching unit 222 can output the first to fourth input data signals ‘data<0:3>_in’ as the second delay data signal group ‘data<0:3>_dl2’. Then, the first delay data signal group ‘data<0:3>_dl1’ output from the first switching unit 221 can be input to the up-bank group 30. Similarly, the second delay data signal group ‘data<0:3>_dl2’ output from the second switching unit 222 can be input to the down-bank group 40.

An exemplary operation of the data transmission circuit and the semiconductor integrated circuit will be described with reference to FIG. 7.

In FIG. 7, if the data strobe signal ‘dinstb’ is enabled, then the data input unit 10 can receive the first to fourth data signals ‘data<0:3>’ to output the first to fourth input data signals ‘data<0:3>_in’.

The controller 210 can enable the first or second selection signal ‘select1’ or ‘select2’ in response to the bank information signals ‘bk_en<0:7>’ and ‘rastb<0:7>’. If the data strobe signal ‘dinstb’ is enabled, then the controller 210 can output the enabled first or second selection signal ‘select1’ or ‘select2’ as the up-signal or down-signal ‘up’ and ‘down’ after the delay time of the first or second delay unit ‘delay11’ or ‘delay12’.

For example, if the first bank enable signal ‘bk_en<0>’ and the first low address strobe signal ‘rastb<0>’ of the bank information signals ‘bk_en<0:7>’ and ‘rastb<0:7>’ are enabled, then a write command is represented for input to the first bank ‘bank0’ of the first to eight banks ‘bank0’ to ‘bank7’. Thus, if the first bank enable signal ‘bk_en<0>’ and the first low address strobe signal ‘rastb<0>’ of the bank information signals ‘bk_en<0:7>’ and ‘rastb<0:7>’ are enabled, then the controller 210 can enable the first selection signal ‘select1’.

Furthermore, if the fifth bank enable signal ‘bk_en<4>’ and the fifth low address strobe signal ‘rastb<4>’ of the bank information signals ‘bk_en<0:7>’ and ‘rastb<0:7>’ are enabled, then a write command is represented for input to the fifth bank ‘bank4’ of the first to eight banks ‘bank0’ to ‘bank7’ is input. Thus, if the fifth bank enable signal ‘bk_en<4>’ and the fifth low address strobe signal ‘rastb<4>’ of the bank information signals ‘bk_en<0:7>’ and ‘rastb<0:7>’ are enabled, then the controller 210 can enable the second selection signal ‘select2’.

If the first selection signal ‘select1’ is enabled and the data strobe signal ‘dinstb’ is enabled, then the up-signal ‘up’ can be enabled after the delay time of the first delay unit ‘delay11’. In addition, if the second selection signal ‘select2’ is enabled and the data strobe signal ‘dinstb’ is enabled, then the down-signal ‘down’ can be enabled after the delay time of the second delay unit ‘delay12’.

If the up-signal ‘up’ is enabled, then the first switching unit 221 can output the first to fourth input data signals ‘data<0:3>_in’ to the up-bank group 30 as the first delay data signal group ‘data<0:3>_dl1’.

If the down-signal ‘down’ is enabled, then the second switching unit 222 can output the first to fourth input data signals ‘data<0:3>_in’ to the down-bank group 40 as the second delay data signal group ‘data<0:3>_dl2’.

Accordingly, current consumption of the data transmission circuit and the semiconductor integrated circuit can be reduced since only one data strobe signal is delayed instead of delaying data on a one-by-one basis. Moreover, current consumption may not be increased even if the number of data is increased. Furthermore, delay data can be output by selecting the up-bank or down-bank group, thereby further reducing current consumption.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A data transmission circuit, comprising:
a data input unit configured to latch data in response to a data strobe signal and to output the data as input data; and
a data input timing control unit configured to latch the input data in response to the data strobe signal delayed for a predetermined time interval and to output the input data to a bank group as delay data.

2. The data transmission circuit of claim 1, wherein the data input timing control unit includes:
a controller configured to generate a control signal by delaying the data strobe signal; and
a switching unit configured to output the input data to the bank group as the delay data in response to the control signal.

3. The data transmission circuit of claim 2, wherein the switching unit latches the input data to output the input data as the delay data if the control signal is enabled.

4. The data transmission circuit of claim 3, wherein the switching unit includes a flip-flop that receives the input data in response to the control signal.

5. The data transmission circuit of claim 1, wherein the bank group includes a plurality of banks, and the data input timing control unit outputs the input data to one bank that is selected from the plurality of banks as the delay data in response to the data strobe signal and a bank information signal.

6. The data transmission circuit of claim 5, wherein the data input timing control unit encodes the bank information signal to select the bank, to which the delay data is input, and outputs the delay data to the selected bank if the data strobe signal is enabled and the predetermined time interval lapses.

7. The data transmission circuit of claim 6, wherein the data input timing control unit includes:
a controller configured to selectively enable one of an up-signal and a down-signal in response to the bank information signal and the data strobe signal; and
a selection switching unit configured to output the input data to a first one of the plurality of banks if the up-signal is enabled, and output the input data to a second one of the plurality of banks if the down-signal is enabled.

8. The data transmission circuit of claim 7, wherein the controller includes:
an encoding unit configured to selectively enable one of a first selection signal and a second selection signal by encoding the bank information signal; and
a selection delay unit configured to output the one of the first selection signal and the second selection signal as one of the up-signal and the down-signal if the data strobe signal is enabled and the predetermined time interval lapses.

9. The data transmission circuit of claim 7, wherein the selection switching unit includes:
a first switching unit configured to output the input data to the first one of the plurality of banks if the up-signal is enabled; and
a second switching unit configured to output the input data to the second one of the plurality of banks if the down-signal is enabled.

10. A semiconductor integrated circuit, comprising:
a plurality of banks, each configured to receive delay data through a global line;
a data input unit configured to latch data in response to a data strobe signal and to output the data as input data; and
a data input timing control unit configured to output the input data to the global line as delay data in response to the data strobe signal.

11. The semiconductor integrated circuit of claim 10, wherein the data input timing control unit includes:
a controller configured to generate a control signal by delaying the data strobe signal; and
a switching unit configured to output the input data to the global line as the delay data in response to the control signal.

12. The semiconductor integrated circuit of claim 11, wherein the switching unit latches the input data to output the input data as the delay data if the control signal is enabled.

13. The semiconductor integrated circuit of claim 12, wherein the switching unit includes a flip-flop that receives the input data in response to the control signal.

14. The semiconductor integrated circuit of claim 10, wherein the global line includes first and second global lines.

15. The semiconductor integrated circuit of claim 14, wherein the plurality of banks include a first bank that receives the delay data through the first global line and a second bank that receives the delay data through the second global line.

16. The semiconductor integrated circuit of claim 15, wherein data input timing control unit selectively outputs the delay data to one of the first global line and the second global line in response to the data strobe signal and a bank information signal.

17. The semiconductor integrated circuit of claim 16, wherein the data input timing control unit encodes the bank information signal to select one of the first global line and the second global line, and outputs the delay data to the selected global line if the data strobe signal is enabled and a predetermined time interval lapses.

18. The semiconductor integrated circuit of claim 17, wherein the data input timing control unit includes:
a controller configured to selectively enable one of an up-signal and a down-signal in response to the bank information signal and the data strobe signal; and
a selection switching unit configured to selectively output the input data to the first global line as the delay data if the up-signal is enabled, and output the input data to the second global line as the delay data if the down-signal is enabled.

19. The semiconductor integrated circuit of claim 18, wherein the controller includes:
an encoding unit configured to encode the bank information signal to selectively enable one of a first selection signal and a second selection signal; and
a selection delay unit configured to output one of the first selection signal and the second selection signal as one of the up-signal and down-signal if the data strobe signal is enabled and the predetermined time interval lapses.

20. The semiconductor integrated circuit of claim 18, wherein the selection switching unit includes:
a first switching unit configured to output the input data to the first global line as the delay data if the up-signal is enabled; and
a second switching unit configured to output the input data to the second global line as the delay data if the down-signal is enabled.

21. A method for data transmission in a semiconductor apparatus, the method comprising:
latching data in response to a data strobe signal;
outputting the data as input data;
delaying the data strobe signal for a predetermined time interval;
latching the input data in response to the delayed data strobe signal; and
outputting the input data as delay data.

22. The method of claim 21, further comprising:
generating a control signal by delaying the data strobe signal; and
outputting the input data as the delay data in response to the control signal.

23. The method of claim 22, further comprising latching the input data to output the input data as the delay data when the control signal is enabled.

24. The method of claim 1, further comprising outputting the input data to a bank that is selected from a plurality of banks as the delay data in response to the data strobe signal and a bank information signal.

25. The method of claim 24, further comprising encoding the bank information signal to select the bank to which the delay data is input, and outputting the delay data to the selected bank if the data strobe signal is enabled and the predetermined time interval lapses.

26. The method of claim 25, further comprising:
selectively enabling one of an up-signal and a down-signal in response to the bank information signal and the data strobe signal; and
outputting the input data to a first one of the plurality of banks if the up-signal is enabled, and outputting the input data to a second one of the plurality of banks if the down-signal is enabled.
